(19) United States
(12) Patent Application Publication
(10) Pub. No.: US 2026/0163577 A1
(43) Pub. Date: Jun. 11, 2026

(54) CLOCK GENERATION CIRCUITRY

(71) Applicant: Cirrus Logic International Semiconductor Ltd., Edinburgh (GB)

(72) Inventors: Luis GOMEZ DURAN, Edinburgh (GB); Erich P. ZWYSSIG, Edinburgh (GB)

(73) Assignee: Cirrus Logic International Semiconductor Ltd., Edinburgh (GB)

(21) Appl. No.: 19/296,151

(22) Filed: Aug. 11, 2025

Related U.S. Application Data
(60) Provisional application No. 63/730,515, filed on Dec. 11, 2024.

(51) Int. Cl. H03L 7/195; H03L 7/083; H03L 7/089

(52) U.S. Cl. CPC H03L 7/195; H03L 7/083; H03L 7/089

(57) ABSTRACT

Clock generation circuitry configured to generate an output clock signal based on a reference clock signal, the clock generation circuitry comprising: monitoring circuitry for monitoring an offset between the output clock signal and the reference clock signal, wherein the clock generation circuitry is configured to adjust generation of the output clock signal based on the offset.

### FIELD OF THE INVENTION

The present disclosure relates to clock generation circuitry.

### BACKGROUND

Clock generation circuits are used in circuits for the generation of clock signals for use with various circuits and systems.

A hybrid phase locked loop (PLL) is an example of a type of clock generation circuit used for clock frequency multiplication and minimising clock jitter. As shown generally at 100 in FIG. 1, a hybrid PLL may comprise an analog PLL 110 and a digital frequency locked loop (FLL) 120.

The analog PLL 110 receives a clean (i.e. high quality) timing reference clock signal REF_CLK_IN and generates an output clock signal CLK_OUT. The digital FLL 120 tracks the frequency of the output clock signal CLK_OUT against the frequency of a frequency reference signal CLK_IN, which may be of a lower quality than the timing reference clock signal REF_CLK_IN (e.g. may be affected by jitter). The digital FLL 120 allows jitter in the timing reference clock signal REF_CLK_IN to be filtered out in generating the output clock signal CLK_OUT.

The output of the digital FLL 120 controls a ratio of the analog PLL 110 in such a way that the output clock signal CLK_OUT can be frequency locked to the reference clock signal CLK_IN, while inheriting the quality (e.g. low jitter characteristics) of the clean reference clock signal REF_CLK_IN.

Examples of clock generation circuits including Hybrid PLLs can be found in U.S. Pat. Nos. 7,049,852; 7,271,666, 7,558,358, 7,667,508, 7,680,236, 7,746,972, and U.S. Pat. No. 9,281,827, the contents of which are incorporated by reference herein.

It is desirable to provide clock generation systems that improve on such existing solutions.

### SUMMARY

According to a first aspect, the invention provides clock generation circuitry configured to generate an output clock signal based on a reference clock signal, the clock generation circuitry comprising: monitoring circuitry for monitoring an offset between the output clock signal and the reference clock signal, wherein the clock generation circuitry is configured to adjust generation of the output clock signal based on the offset.

The offset may be a phase offset.

The clock generation circuitry may further comprise controller circuitry configured to receive an indication of the offset and to output a control signal to adjust generation of the output clock signal based on the indication of the offset.

The indication of the offset may comprise a signal indicative of a magnitude of the offset.

The controller circuitry may be configured to read the indication of the offset from a memory of the clock generation circuitry.

The clock generation circuitry may be configured to transmit the indication of the offset to the controller circuitry.

The indication of the offset may comprise a signal flag.

The signal flag may be generated by the clock generation circuitry in response to a determination that the offset exceeds a threshold offset level.

The threshold offset level may be a predetermined threshold offset level.

Alternatively, the threshold level may be adjustable.

The clock generation circuitry may comprise hybrid phase locked loop (PLL) circuitry configured to receive a timing reference clock signal and a frequency reference clock signal and to output an output clock signal.

The hybrid PLL circuitry may comprise analog PLL circuitry and digital frequency locked loop (FLL) circuitry, wherein the digital FLL circuitry is configured to receive the frequency reference clock signal and the output clock signal, and to generate a control signal for controlling a parameter or characteristic of the hybrid PLL circuitry.

The parameter or characteristic may comprise an input frequency to output frequency ratio of the analog PLL circuitry.

The clock generation circuitry may further comprise controller circuitry configured to receive an indication of the offset and to output a control signal to control a parameter or characteristic of the hybrid PLL circuitry based on the offset. p The clock generation circuitry may be implemented in an integrated circuit.

The clock generation circuitry may be selectively operable in a first mode or a second mode. In operation of the clock generation circuitry in the first mode, the clock generation circuitry may be configured to adjust a duration of a period of the output clock signal to compensate for the offset. In operation of the clock generation circuitry in the second mode, the clock generation circuitry may be configured to adjust generation of the output clock signal based on the offset.

The clock generation circuitry may be operable to select between the first mode of operation and the second mode of operation based on a mode control signal. The mode control signal may be: received from a host device or system that incorporates the clock generation circuitry; or based on a magnitude of the offset; or based on a timeout period.

According to a second aspect, the invention provides a system comprising: a clock generation IC configured to: generate an output clock signal based on a reference clock signal; and generate an indication of a phase offset between the reference clock signal and the output clock signal; and controller circuitry, external to the clock generation IC configured to: receive the indication of the phase offset; and output a control signal based on the phase offset to the clock generation IC, wherein the clock generation IC is operative to adjust generation of the output clock signal based on the control signal.

According to a third aspect, the invention provides multi-mode clock generation circuitry configured to receive an input clock signal and generate an output clock signal, wherein the multi-mode clock generation circuitry is operable in: a first mode, in which a duration of a period of the output clock signal is adjusted based on an indication of an offset between the input clock signal and the output clock signal to compensate for the offset; and a second mode, in which generation of the output clock signal is adjusted based on the indication of the offset between the input clock signal and the output clock signal to compensate for the offset.

According to a fourth aspect, the invention provides a host device comprising clock generation circuitry according to the first, second or third aspect.

The host device may comprise, for example, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a simplified schematic representation of a hybrid phase locked loop (PLL);

FIG. 2 is a is a simplified schematic representation of clock generation circuitry comprising hybrid PLL circuitry and phase alignment circuitry; and

FIG. 3 is a schematic representation of clock generation circuitry according to the present disclosure.

### DETAILED DESCRIPTION

Due to the nature of the hybrid PLL 100, although the output clock signal CLK_OUT is frequency locked to the frequency reference signal CLK_IN, the output clock signal CLK_OUT is generated from the analog PLL 110 which receives the clean timing reference clock signal REF_CLK_IN. Accordingly, the output clock signal CLK_OUT will be phase locked to the clean timing reference clock signal REF_CLK_IN.

This architecture allows generation of a low-jitter output clock signal that is frequency locked to the frequency reference signal CLK_IN, but is in phase (or synchrony) with the clean timing reference clock signal REF_CLK_IN.

The hybrid PLL 100 may include a first divider 130 configured to receive the output clock signal CLK_OUT and generate a bit clock output signal BCLK_OUT, and a second divider 140 configured to receive the output clock signal CLK_OUT and generate a frame synchronisation output signal FSYNC_OUT. The bit clock output signal BCLK_OUT signal and the frame synchronisation output signal FSYNC_OUT are thus both derived from the output clock signal CLK_OUT.

Some applications can require the bit clock output signal BCLK_OUT and the frame synchronisation output signal FSYNC_OUT to be both frequency locked and in phase with the frequency reference signal CLK_IN.

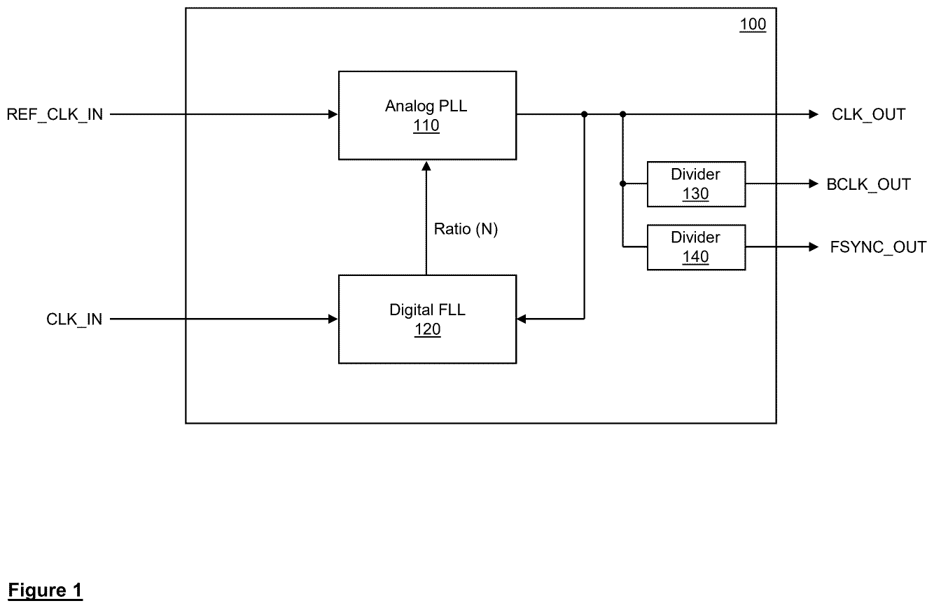

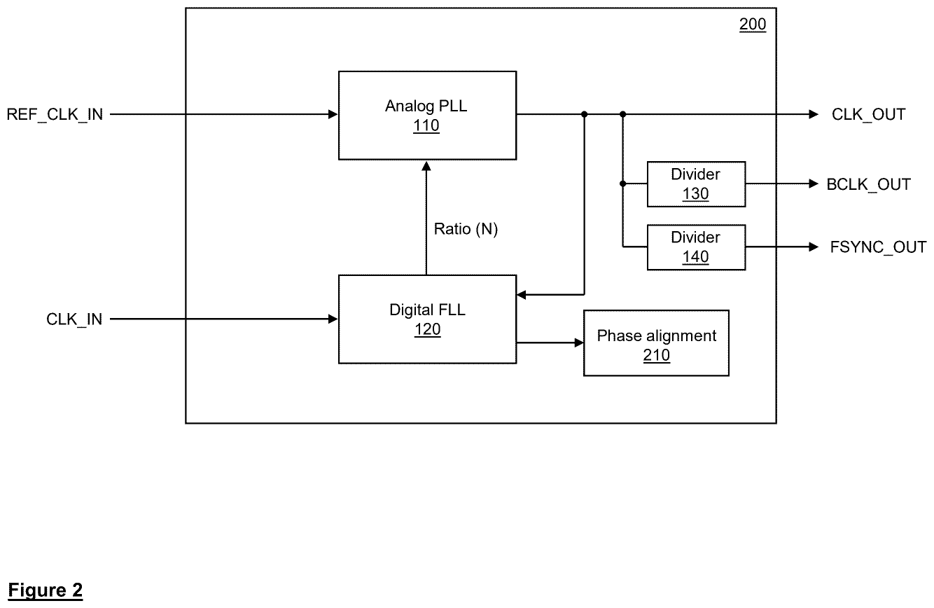

To meet this requirement, clock generation circuitry (shown generally at 200 in FIG. 2), which may be implemented in an integrated circuit (IC) that includes hybrid PLL circuitry of the kind described above with reference to FIG. 1 (comprising an analog PLL 110 and a digital FLL 120 in a feedback loop from an output of the analog PLL 110) may include phase alignment circuitry 210, outside of the feedback loop.

The phase alignment circuitry 210 is configured to monitor a phase offset between the frequency reference signal CLK_IN and the bit clock output signal BCLK_OUT or the frame synchronisation output signal FSYNC_OUT, and to adjust (e.g. lengthen) a duration of one or more frame synchronisation signal periods and/or of one or more bit clock output signal periods, to compensate for any detected phase difference to restore phase alignment between the input clock signal CLK_IN and the output frame synchronisation signal FSYNC and/or the bit clock output signal BCLK_OUT.

Such an implementation is described in U.S. patent application Ser. No. 18/907,479, the contents of which are incorporated by reference herein.

However, such adjustment of the period of the frame synchronisation output signal FSYNC_OUT and/or the bit clock output signal BLCK_OUT may have an adverse impact on downstream timed devices, which might require a smoother transitory change in the frequency of the frame synchronisation output signal FSYNC_OUT and/or the bit clock output signal BLCK_OUT, to maintain or restore phase alignment between the input clock signal CLK_IN and the output frame synchronisation signal FSYNC and/or the bit clock output signal BCLK_OUT.

The present disclosure proposes clock generation circuitry (which may be implemented in an integrated circuit) having monitoring circuitry for monitoring a phase offset between an output clock signal and a reference clock signal on which the output clock signal is based, wherein the clock generation circuitry is configured to adjust generation of the output clock signal based on the phase offset, to restore phase alignment between the reference clock signal and the output clock signal.

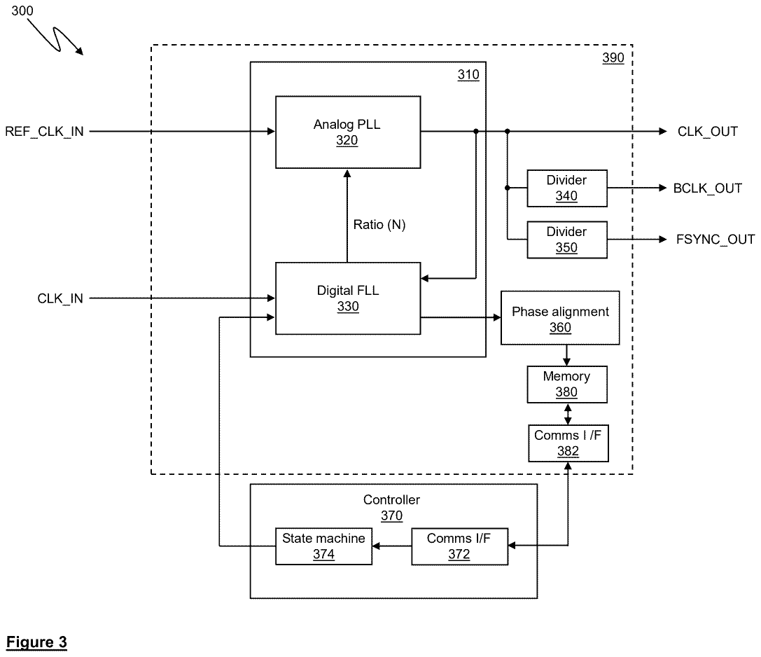

FIG. 3 is as schematic representation of clock generation circuitry according to the present disclosure.

The clock generation circuitry, shown generally at 300 in FIG. 3, includes hybrid PLL circuitry 310 comprising analog PLL circuitry 320 and digital FLL circuitry 330.

The hybrid PLL circuitry 310 is configured to receive a high-quality (e.g. low-jitter) timing reference clock signal REF_CLK_IN, e.g. from a crystal oscillator or other stable timing reference, and an input frequency reference clock signal CLK_IN, which may be of a lower quality (e.g. may have more jitter) than the timing reference clock signal REF_CLK_IN.

The hybrid PLL circuitry 310 is configured to generate an output clock signal CLK_OUT at the frequency of the input frequency reference clock signal CLK_IN with the jitter characteristics of the timing reference clock signal REF_CLK_IN.

To this end, the analog PLL circuitry 320 is configured to receive the timing reference clock signal REF_CLK_IN and generate the output clock signal CLK_OUT. The digital FLL circuitry 330 is configured to receive the input frequency reference clock signal CLK_IN and the output clock signal CLK_OUT and to generate a control signal for controlling an input frequency to output frequency ratio of the analog PLL circuitry 320, based on the input frequency reference clock signal CLK_IN and the output clock signal CLK_OUT. This control signal is output to the analog PLL circuitry 320. In this way, the output clock signal CLK_OUT has the frequency of the input frequency reference clock signal CLK_IN with the jitter characteristics of the timing reference clock signal REF_CLK_IN.

The output clock signal CLK_OUT is received by first divider circuitry 340, which is configured to generate a bit clock output signal BCLK_OUT by dividing the frequency of the output clock signal CLK_OUT by a first predefined value. The output clock signal CLK_OUT is also received by second divider circuitry 350, which is configured to generate an output frame synchronisation signal FSYNC by dividing the frequency of the output clock signal CLK_OUT by a second predefined value.

The clock generation circuitry 300 further includes phase alignment circuitry 360, configured to monitor a phase offset between the input frequency reference clock signal CLK_IN and the bit clock output signal BCLK_OUT and/or a phase offset between the input frequency reference clock signal CLK_IN and the output frame synchronisation signal FSYNC. The phase alignment circuitry 360 may be configured to determine a phase offset between the input frequency reference clock signal CLK_IN and the bit clock output signal BCLK_OUT or the output frame synchronisation signal FSYNC based, for example, on the input frequency reference clock signal CLK_IN and the output clock signal CLK_OUT.

The clock generation circuitry 300 further includes controller circuitry 370 configured to receive an indication of the determined phase offset between the input frequency reference clock signal CLK_IN and the bit clock output signal BCLK_OUT and/or a signal indicative of the determined phase offset between the input frequency reference clock signal CLK_IN and the output frame synchronisation signal FSYNC.

In some examples, the phase alignment circuitry 360 is configured to store the determined phase offset in a memory 380 of the clock generation circuitry 300. The memory 380 is accessible to a communications interface 382, which may be a serial peripheral interface (SPI) or inter-IC communications (I²C) interface, for example.

The controller circuitry 370 may be configured to periodically read the determined phase offset from the memory 380, e.g. via a communications interface 372 (e.g. an SPI or I²C interface) of the controller circuitry 370.

Additionally or alternatively, the clock generation circuitry 300 (e.g. the phase alignment circuitry 360) may be configured to periodically transmit a signal indicative of the determined phase offset to the controller circuitry 370, e.g. via the communications interface 382 of the clock generation circuitry 300 and the communications interface 372 of the controller circuitry 370.

Additionally or alternatively, the clock generation circuitry 300 (e.g. the phase alignment circuitry 360) may be configured to compare the determined phase offset to a threshold offset level and to generate a signal flag in response to a determination that the determined phase offset exceeds the threshold offset level. The signal flag is thus indicative of the determined phase offset. The threshold offset level may be a predefined threshold offset level, or may be adjustable such that the threshold offset level can be defined based on one or more characteristics of a host device or system that incorporates the clock generation circuitry 300, e.g. by a user of the host device or system, or during a production test or calibration process for the host device or system.

The controller circuitry 370 is configured to generate a ratio control signal based on the determined phase offset, and to output the ratio control signal to the digital FLL circuitry 330.

In the example illustrated in FIG. 3, the controller circuitry 370 includes a state machine 374 configured to receive the determined phase offset and to generate the ratio control signal, but it will be appreciated by those of ordinary skill in the art that the ratio control signal could be generated by any other suitable means, e.g. a microprocessor, microcontroller or the like.

The ratio control signal output by the controller circuitry 370 controls the input frequency to output frequency ratio of the analog PLL circuitry 320 based on the determined phase offset. This has the effect of altering the frequency of the output clock signal CLK_OUT (and thus also the frequency of the bit clock output signal BCLK_OUT and the frame synchronisation output signal FSYNC_OUT), to restore phase alignment between the input clock signal CLK_IN and the output frame synchronisation signal FSYNC and/or the bit clock output signal BCLK_OUT.

As the ratio control signal generated by the controller circuitry 370 is based on the determined phase offset, as the phase offset changes, the ratio control signal also changes. When the phase offset has fallen to zero, or below a predetermined phase offset threshold, the controller circuitry 370 stops outputting the ratio control signal, or alternatively outputs a predefined ratio control signal, to cause the digital FLL circuitry 330 to revert to outputting a control signal based on the input clock signal CLK_IN and the output clock signal CLK_OUT to the analog PLL circuitry 320, such that such that the input frequency to output frequency ratio of the analog PLL circuitry 320 returns to a ratio that was in use before a phase misalignment was detected by the phase alignment circuitry 360.

Thus, the clock generation circuitry 300 is configured to adjust the generation of the output clock signal CLK_OUT, and thus also the generation of the bit clock output signal BCLK_OUT and the frame synchronisation output signal FSYNC_OUT, based on the determined phase offset.

The hybrid PLL circuitry 310, first and second divider circuitry 340, 350, phase alignment circuitry 360, memory 380 and communications interface 382 may be implemented in a single integrated circuit (IC) 390. In some examples, the controller circuitry 370 may be external to the IC 390, i.e. the controller circuitry 370 may be off-chip. In other examples, the controller circuitry 370 may be provided on-chip, i.e. integrated with the hybrid PLL circuitry 310, first and second divider circuitry 340, 350, phase alignment circuitry 360, memory 380 and communications interface 382 on the IC 390.

In some examples, the clock generation circuitry 300 is selectively operable in a first mode or a second mode.

In the first mode, the phase alignment circuitry 360 is operative to monitor the phase offset between the frequency reference signal CLK_IN and the bit clock output signal BCLK_OUT or the frame synchronisation output signal FSYNC_OUT, and to adjust (e.g. lengthen) the duration of one or more frame synchronisation signal periods and/or of one or more bit clock output signal periods, to compensate for any detected phase difference to restore phase alignment between the input clock signal CLK_IN and the output frame synchronisation signal FSYNC and/or the bit clock output signal BCLK_OUT, as described in U.S. patent application Ser. No. 18/907,479.

In the second mode, the clock generation circuitry 300 is operative to adjust generation of the output clock signal CLK_OUT (and thus also the generation of the bit clock output signal BCLK_OUT and the frame synchronisation output signal FSYNC_OUT) based on the determined phase offset, as described above with reference to FIG. 3.

The clock generation circuitry 300 may be operable to select a mode of operation (e.g. to select between the first mode of operation and the second mode of operation) based on a mode control signal. The mode control signal may be received from a host device that incorporates the clock generation circuitry 300, e.g. from a main or central processor of the host device. The mode control signal may be implemented by writing a control value to a register of the clock generation circuitry 300.

Additionally or alternatively, the clock generation circuitry 300 may be operable to switch between modes based on a magnitude of the determined phase offset. For example, the phase alignment circuitry 360 may be configured to compare the determined phase offset to a first mode control threshold and a second mode control threshold which is greater than the first threshold, and to output a mode control signal based on these comparisons. If the determined phase offset is equal to or greater than the first mode control threshold, but less than the second mode control threshold, the phase alignment circuitry 360 may output a first control signal to cause the clock generation circuitry 300 to operate in the first mode of operation. If the determined phase offset is equal to or greater than the second mode control threshold, the phase alignment circuitry 360 may output a second control signal to cause the clock generation circuitry 300 to operate in the second mode of operation. The first and second mode control signals may be implemented by writing suitable control values to one or more registers of the clock generation circuitry 300.

Additionally or alternatively, in examples in which the determined phase offset is signalled by a signal flag, the clock generation circuitry 300 may be operable to switch between the first mode of operation and the second mode of operation based on a timeout. For example, when the clock generation circuitry 300 is operating in the second mode of operation, the clock generation circuitry 300 may be operable to switch to the first mode of operation if a predefined timeout period has elapsed from the generation of the signal flag without a control input having been received from the controller circuitry 370.

The clock generation circuitry 300 described above with reference to FIG. 3 is operative to monitor a phase offset between an input clock signal (the frequency reference signal CLK_IN) and an output clock signal (e.g. the output clock signal CLK_OUT, the bit clock output signal BCLK_OUT or the frame synchronisation signal FSYNC_OUT), and to adjust generation of the output clock signal based on the phase offset. In other examples, however, the clock generation circuitry 300 may be operative to monitor a frequency offset between an input clock signal and an output clock signal and to adjust generation of the output clock signal based on the frequency offset.

In the clock generation circuitry 300 described above, the controller circuitry 370 is configured to output a ratio control signal based on the determined offset to control the input frequency to output frequency ratio of the analog PLL circuitry 320, to correct (at least partially) the detected offset. In other examples, however, the controller circuitry 370 may be operative to generate a control signal based on the determined offset to control to control some other parameter or characteristic of the hybrid PLL circuitry 310 (e.g. a parameter or characteristic of the analog PLL circuitry 320) to correct (at least partially) the detected offset.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

### The Paragraphs Below Describe Aspects of the Present Disclosure.

The present disclosure provides a clock generation integrated circuit (or IC) operable to generate one or more output clocks based on one or more reference clocks, wherein the clock generation IC comprises a controller arranged to: monitor a phase offset between the one or more output clocks and the one or more reference clocks, output a signal indicative of the monitored offset to an external device, receive a control input from the external device based on the signal output, and adjust generation of the one or more output clocks based on the received control input.

The signal indicative of the monitored offset may comprise a system flag indicative that the monitored offset has exceeded a threshold, or the signal may comprise the monitored offset value itself communicated to the external device.

While the above system is described in the context of a phase offset, it will be understood that the system may also be used for the monitoring of a frequency offset.

Preferably, the clock generation IC is operable in two modes: an on-chip control mode wherein the controller adjusts generation of the one or more output clocks based on the monitored offset; and an off-chip control mode wherein the controller adjusts generation of the one or more output clocks based on the received control input.

Preferably, when in the on-chip control mode, the controller is operable to adjust the phase and/or frequency of the one or more output clocks to reduce the monitored offset.

In one implementation, the controller is operable to stretch or lengthen the period of the one or more output clocks to reduce the monitored offset.

Preferably, the controller stores the monitored offset value in memory, wherein the memory is accessible by an external device via an interface provided on the IC, e.g. via an I²C interface.

Additionally or alternatively, the controller may be operable to generate an offset flag when the monitored offset exceeds a threshold value, wherein the offset flag can be output to an external device, for example as an interrupt signal.

Preferably, the threshold value is adjustable. For example an external device may set the threshold value for the generation of the offset flag based on the characteristics of the system wherein the clock generation IC is used.

Preferably, the clock generation IC can be switched between the two modes based on a mode control signal received from an external device. This may be by writing a control value to a register of the clock generation IC.

Additionally or alternatively, the clock generation IC may switch between modes based on a time-out. For example when in the off-chip control mode, if a time period has elapsed from the generation of an offset flag without a control input received from the external controller, the clock generation IC may switch to the on-chip control mode.

In a further variation, when in the off-chip control mode, if the monitored offset exceeds a second higher threshold, the clock generation IC may switch to the on-chip control mode, to force phase alignment of the one or more output clocks. The second higher threshold may be a predefined threshold value, or a threshold set by a user to be higher than the initial offset threshold value.

Preferably, the clock generation IC comprises a Hybrid PLL Core to generate one or more output clocks based on one or more reference clocks, the Hybrid PLL Core comprising an analog PLL and a digital FLL, the digital FLL used to control a characteristic of the analog PLL, preferably a ratio of the analog PLL, wherein an external device can generate a control input to adjust the characteristic between the digital FLL and the analog PLL to reduce a monitored offset.

The present disclosure also provides a clocking system comprising the clock generation IC as described above coupled with an external controller, wherein the external controller is operable to adjust operation of the clock generation IC based on a phase and/or frequency offset monitored by the clock generation IC and communicated to the external controller.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. Clock generation circuitry configured to generate an output clock signal based on a reference clock signal, the clock generation circuitry comprising:
monitoring circuitry for monitoring an offset between the output clock signal and the reference clock signal,
wherein the clock generation circuitry is configured to adjust generation of the output clock signal based on the offset.

2. The clock generation circuitry of claim 1, wherein the offset is a phase offset.

3. The clock generation circuitry of claim 1, further comprising controller circuitry configured to receive an indication of the offset and to output a control signal to adjust generation of the output clock signal based on the indication of the offset.

4. The clock generation circuitry of claim 3, wherein the indication of the offset comprises a signal indicative of a magnitude of the offset.

5. The clock generation circuitry of claim 4, wherein the controller circuitry is configured to read the indication of the offset from a memory of the clock generation circuitry.

6. The clock generation circuitry of claim 4, wherein the clock generation circuitry is configured to transmit the indication of the offset to the controller circuitry.

7. The clock generation circuitry of claim 3, wherein the indication of the offset comprises a signal flag.

8. The clock generation circuitry of claim 7, wherein the signal flag is generated by the clock generation circuitry in response to a determination that the offset exceeds a threshold offset level.

9. The clock generation circuitry of claim 8, wherein the threshold offset level is a predetermined threshold offset level, or wherein the threshold level is adjustable.

10. The clock generation circuitry of claim 1, wherein the clock generation circuitry comprises hybrid phase locked loop (PLL) circuitry configured to receive a timing reference clock signal and a frequency reference clock signal and to output an output clock signal.

11. The clock generation circuitry of claim 10, wherein the hybrid PLL circuitry comprises analog PLL circuitry and digital frequency locked loop (FLL) circuitry, wherein the digital FLL circuitry is configured to receive the frequency reference clock signal and the output clock signal, and to generate a control signal for controlling a parameter or characteristic of the hybrid PLL circuitry.

12. The clock generation circuitry of claim 11, wherein the parameter or characteristic comprises an input frequency to output frequency ratio of the analog PLL circuitry.

13. The clock generation circuitry of claim 10, further comprising controller circuitry configured to receive an indication of the offset and to output a control signal to control a parameter or characteristic of the hybrid PLL circuitry based on the offset.

14. The clock generation circuitry of claim 1, wherein the clock generation circuitry is implemented in an integrated circuit.

15. The clock generation circuitry of claim 1, wherein the clock generation circuitry is selectively operable in a first mode or a second mode, wherein:
in operation of the clock generation circuitry in the first mode, the clock generation circuitry is configured to adjust a duration of a period of the output clock signal to compensate for the offset; and
in operation of the clock generation circuitry in the second mode, the clock generation circuitry is configured to adjust generation of the output clock signal based on the offset.

16. The clock generation circuitry of claim 15, wherein the clock generation circuitry is operable to select between the first mode of operation and the second mode of operation based on a mode control signal, wherein the mode control signal is:
received from a host device or system that incorporates the clock generation circuitry; or
based on a magnitude of the offset; or
based on a timeout period.

17. A system comprising:
a clock generation IC configured to:
generate an output clock signal based on a reference clock signal; and
generate an indication of a phase offset between the reference clock signal and the output clock signal; and
controller circuitry, external to the clock generation IC configured to:
receive the indication of the phase offset; and
output a control signal based on the phase offset to the clock generation IC,
wherein the clock generation IC is operative to adjust generation of the output clock signal based on the control signal.

18. Multi-mode clock generation circuitry configured to receive an input clock signal and generate an output clock signal, wherein the multi-mode clock generation circuitry is operable in:
a first mode, in which a duration of a period of the output clock signal is adjusted based on an indication of an offset between the input clock signal and the output clock signal to compensate for the offset; and
a second mode, in which generation of the output clock signal is adjusted based on the indication of the offset between the input clock signal and the output clock signal to compensate for the offset.

19. A host device comprising clock generation circuitry according to claim 1.

20. A host device according to claim 19, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.
